(19) United States
(12) Patent Application Publication
(10) Pub. No.: US 2017/0012186 A1
(43) Pub. Date: Jan. 12, 2017

(54) NOVEL WHITE LIGHT LED PACKAGING STRUCTURE AND PROCESS FOR MANUFACTURING THE SAME

(71) Applicants: Dun-Hua Cao, Kunshan Suzhou (CN); Yue-Shan Liang, Kunshan Suzhou (CN); Kejun Ma, Kunshan Suzhou (CN)

(72) Inventors: Dun-Hua Cao, Kunshan Suzhou (CN); Yue-Shan Liang, Kunshan Suzhou (CN); Kejun Ma, Kunshan Suzhou (CN)

(21) Appl. No.: 14/795,645

(22) Filed: Jul. 9, 2015

(51) Int. Cl. H01L 33/60; H01L 33/50

(52) U.S. Cl. CPC H01L 33/60; H01L 33/502; H01L 2933/0041; H01L 2933/0058

(57) ABSTRACT

The present invention relates to a novel white light LED packaging structure and a process for manufacturing the same. An anti-blue light reflection film(s) is deposited on one surface of a fluorescent wafer, wherein the surface is attached to a blue-emitting chip. The anti-blue light reflection film(s) on the wafer can effectively prevent the incident blue light from reflecting on the surface of the wafer, increase the availability of the blue light and reduce the reflection loss of yellowish green light in the direction towards the chip, and thereby improving the whole luminous efficacy of the device. The white light LED packaging structure of the present invention has high fluorescence efficiency, and is suitable for applying in high-power white light LED illumination field.

### TECHNICAL FIELD OF THE INVENTION

The present invention relates to LED luminous technique field, and in particular, relates to a novel white light LED packaging structure and a process for manufacturing the same.

### TECHNICAL BACKGROUND

LED is a solid semiconductor device which can directly convert electric energy into light energy. As compared to conventional incandescent lamp and fluorescent lamp, white light LED shows the advantages of low power consumption, high luminescence efficiency, long service life, energy saving and environmental protection, and so on. Consequently, it is not only widely used for daily illumination, but also enters the display device field. Currently, techniques for obtaining white light LED can be classified into the following two classes: (1) mixing three types of LED chips which emit red light, green light and blue light, respectively; and (2) exciting a suitable fluorescent material with a single color (blue or UV) LED chip. White light LED is mainly produced nowadays by using the combination of blue-emitting LED chips and yellow-emitting fluorescent powder Ce:YAG which can be effectively excited by blue light, whereby the complementary yellow light and the blue light are mixed to produce white light based on the lens principle.

Recently, fluorescent wafers are used as a replacement of fluorescent powders to avoid the disadvantages of fluorescent powders, i.e., low excitation efficiency, low light conversion efficiency and low homogeneity. However, a conventional fluorescent wafer has a single structure, and the properties thereof are not optimized.

### CONTENTS OF THE INVENTION

The technical problem to be solved by the present invention is to overcome the drawbacks in the prior art and to provide a novel white light LED packaging structure. An anti-blue light reflection film(s) is deposited on one surface of a fluorescent wafer, wherein the surface is attached to a blue-emitting chip. White light is obtained by mixing the blue light emitted by the chip and the yellowish green light converted by the wafer via lens principle. The anti-blue light reflection film(s) on the surface of the wafer can effectively prevent the incident blue light from reflecting on the surface of the wafer, increase the availability of the blue light and reduce the reflection loss of yellowish green light in the direction towards the chip, thereby improving the whole luminous efficacy of the device. The white light LED packaging structure shows high fluorescence efficiency, and is suitable for applying in high-power white light LED illumination field.

To solve the above technical problem, the present invention provides a novel white light LED packaging structure comprising: a blue-emitting chip; a fluorescent wafer attached to the blue-emitting chip; and, an anti-blue light reflection film(s) deposited on one surface of the fluorescent wafer, wherein the surface is attached to the blue-emitting chip.

Furthermore, the main component of the fluorescent wafer is Ce:YAG.

Furthermore, the main component of the anti-blue light reflection film(s) is one of titanium oxide, silicon oxide, aluminium oxide, and zirconium oxide, or any combination thereof

Furthermore, the light transmission wave band of the anti-blue light reflection film(s) is 420 nm˜470 nm.

Furthermore, multiple layers of anti-blue light reflection films are used.

To solve the above technical problem, the present invention further provides a process for manufacturing a novel white light LED packaging structure comprising the steps of:

(1) producing a Ce:YAG wafer by Czochralski process, temperature gradient process or Kyropoulos process;

(2) cutting and polishing the Ce:YAG wafer produced in step (1) to obtain a fluorescent wafer having desired size;

(3) depositing an anti-blue light reflection film(s) on one surface of the Ce:YAG wafer obtained in step (2) by physical vapor deposition; and

(4) attaching a blue-emitting chip on the deposited surface of the Ce:YAG wafer obtained in step (3) to carry out the packaging.

As compared to prior art, the white light LED packaging structure comprising fluorescent wafer which is manufactured by the process of the present invention shows the following beneficial effects:

1) as compared to fluorescent powders, the deposited Ce:YAG fluorescent wafer has high excitation efficiency and high light conversion efficiency; better homogeneity; excellent physical-chemical properties; and small light decay.

2) as compared to a conventional Ce:YAG fluorescent wafer, the Ce:YAG fluorescent wafer deposited with an anti-blue light reflection film(s) shows higher luminous efficacy, wherein the luminous efficacy of a white light LED device using the wafer of the present invention is 5˜10% higher than that of devices using a conventional wafer.

3) the transmittance of the anti-blue light reflection film(s) on the surface of the wafer to blue light having a wave band of 420 nm˜470 nm is up to 99.5%, and the main peak of the excitation wavelength of a blue-emitting chip currently used in a white light LED is about 448 nm. Consequently, the structure of the present invention can effectively prevent the incident blue light from reflecting on the surface of the wafer and increase the availability of the blue light, as well as reduce the reflection loss of yellowish green light in the direction towards the chip by full reflection of the anti-blue light reflection film(s) to yellowish green light having a wavelength of 500 nm˜730 nm, thereby effectively improving the whole luminous efficacy of the device.

### BRIEF DESCRIPTION OF THE DRAWINGS

FIG. 1 is a schematic diagram for illustrating the structure in the example(s) of the present invention.

FIG. 2 is the transmittance curve of the fluorescent wafer deposited with anti-blue light reflection films in Example 1.

FIG. 3 shows relative energy distribution curves for the fluorescent wafer deposited with anti-blue light reflection films in Example 1 and a conventional wafer in the Comparative Example.

In the figures, “1”: Ce:YAG fluorescent wafer; “2”: blue-emitting chip; “3”: anti-blue light reflection film(s); “4”: energy distribution curve for the wafer deposited with anti-blue light reflection film(s); “5”: energy distribution curve for a conventional wafer.

### DETAILED DESCRIPTION OF THE EMBODIMENTS

The present invention will be further illustrated by examples referencing the accompanying drawings.

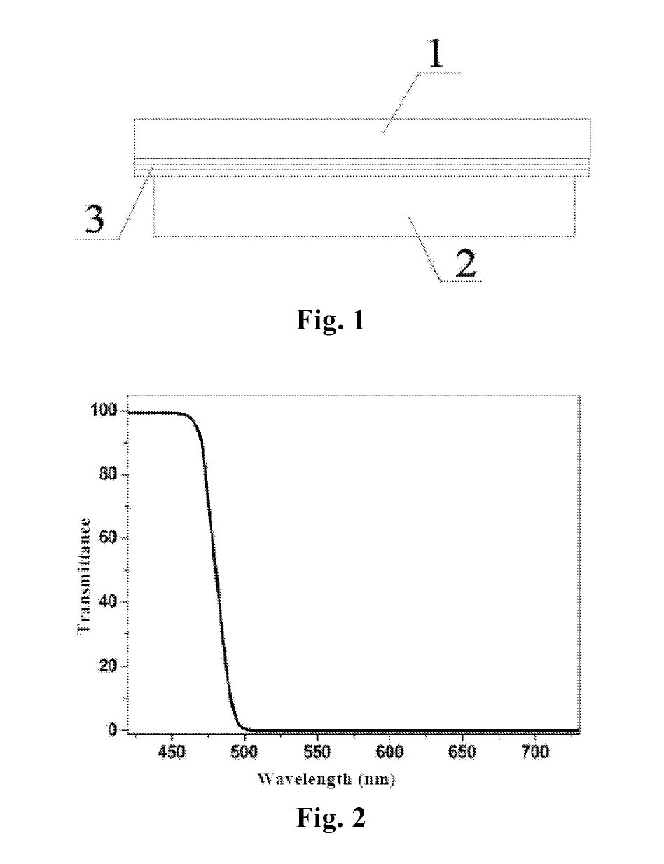

FIG. 1 is a schematic diagram for illustrating the structure in the examples of the present invention: a novel white light LED packaging structure comprising: a blue-emitting chip 2; a Ce:YAG fluorescent wafer 1 attached to the blue-emitting chip; and, anti-blue light reflection films 3 deposited on one surface of the fluorescent wafer 1, wherein the surface is attached to the blue-emitting chip 2. The main component of the fluorescent wafer 1 produced by Czochralski process, temperature gradient process or Kyropoulos process is Ce:YAG. Multiple layers of anti-blue light reflection films 3 are used, wherein the main component of the films is one of titanium oxide, silicon oxide, aluminium oxide, and zirconium oxide, or any combination thereof, and wherein the light transmission wave band of the anti-blue light reflection film(s) is 420 nm˜470 nm.

In a process for manufacturing the novel white light LED packaging structure, Ce-doped YAG is prepared by Czochralski process, temperature gradient process or Kyropoulos process; the obtained Ce-doped YAG is cut and polished to produce a fluorescent wafer having desired size (according to the needs in the practice, the shape of the wafer can be selected from, but is not limited to, strip, sheet and round shape); then, anti-blue light reflection films are deposited on one surface of the obtained Ce:YAG wafer by physical vapor deposition; and finally, a blue-emitting chip is attached to the deposited surface of the Ce:YAG wafer to carry out the packaging.

### EXAMPLE 1

Ce-doped YAG was prepared by Czochralski process; the obtained Ce:YAG wafer was polished to produce a round wafer having a thickness of 0.3 mm and a diameter of 50 mm; ten layers of anti-blue light reflection films were deposited onto one surface of the obtained round wafer; then, the deposited round wafer was cut into small square wafers having a side length of 4 mm; and finally, a blue-emitting chip was tightly attached to the deposited surface of the small wafer so as produce a packaged white light LED device.

### EXAMPLE 2

Ce-doped YAG was prepared by Czochralski process; the obtained Ce:YAG wafer was polished to produce a round wafer having a thickness of 0.35 mm and a diameter of 50 mm; fifteen layers of anti-blue light reflection films were deposited onto one surface of the obtained round wafer; then, the deposited round wafer was cut into small square wafers having a side length of 5 mm; and finally, a blue-emitting chip was tightly attached to the deposited surface of the small wafer so as produce a packaged white light LED device.

### EXAMPLE 3

Ce-doped YAG was prepared by Czochralski process; the obtained Ce:YAG wafer was polished to produce a round wafer having a thickness of 0.4 mm and a diameter of 75 mm; twenty layers of anti-blue light reflection films were deposited onto one surface of the obtained round wafer; then, the deposited round wafer was cut into small square wafers having a side length of 5 mm; and finally, a blue-emitting chip was tightly attached to the deposited surface of the small wafer so as produce a packaged white light LED device.

### COMPARATIVE EXAMPLE

Ce-doped YAG was prepared by Czochralski process; the obtained Ce:YAG wafer was polished to produce a round wafer having a thickness of 0.3 mm and a diameter of 50 mm; then, the round wafer was cut into small square wafers having a side length of 4 mm; and finally, a blue-emitting chip was tightly attached to the surface of the small wafer so as produce a packaged white light LED device.

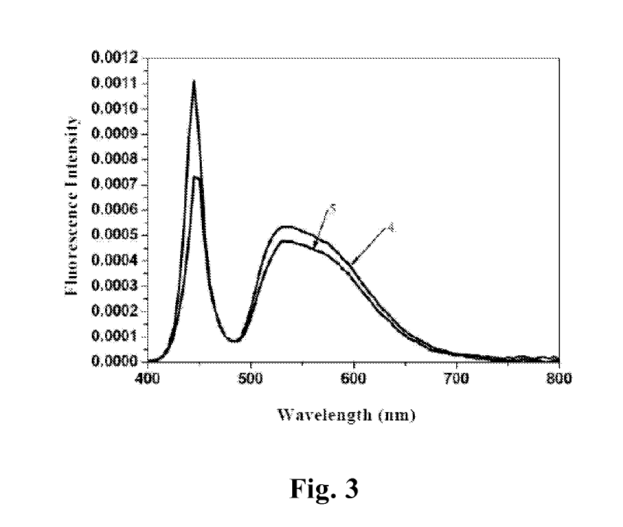

FIG. 2 is the transmittance curve of the fluorescent wafer deposited with anti-blue light reflection films in Example 1, which shows that the transmittance of the anti-blue light reflection films on the surface of the wafer to blue light having a wave band of 420 nm˜470 nm is up to 99.5%.

FIG. 3 is relative energy distribution curves for the fluorescent wafer deposited with anti-blue light reflection films in Example 1 and a conventional wafer in the Comparative Example. The white light LED structure using a wafer deposited with anti-blue light reflection films displays the following properties: luminous efficacy: 158.5; color temperature: 6723 K; color rendering index: 66.5. As for the white light LED structure using a conventional wafer, it shows the following properties: luminous efficacy: 145.8; color temperature: 6065 K; color rendering index: 65.0. It can be seen that the white light LED structure using a wafer deposited with anti-blue light reflection films has better luminous efficacy.

As compared to prior art, the white light LED packaging structure comprising a fluorescent wafer which is manufactured by the process of the present invention shows the following beneficial effects:

1) as compared to fluorescent powders, the deposited Ce:YAG fluorescent wafer has high excitation efficiency and high light conversion efficiency; better homogeneity; excellent physical-chemical properties; and small light decay.

2) as compared to a conventional Ce:YAG fluorescent wafer, the Ce:YAG fluorescent wafer deposited with an anti-blue light reflection film(s) shows higher luminous efficacy, wherein the luminous efficacy of a white light LED device using the wafer of the present invention is 5˜10% higher than that of devices using a conventional wafer.

3) the transmittance of the anti-blue light reflection film(s) on the surface of the wafer to blue light having a wave band of 420 nm˜470 nm is up to 99.5%, and the main peak of the excitation wavelength of a blue-emitting chip currently used in a white light LED is about 448 nm. Consequently, the structure of the present invention can effectively prevent the incident blue light from reflecting on the surface of the wafer and increase the availability of the blue light, as well as reduce the reflection loss of yellowish green light in the direction towards the chip by full reflection of the anti-blue light reflection film(s) to yellowish green light having a wavelength of 500 nm˜730 nm, thereby effectively improving the whole luminous efficacy of the device.

The purpose, technical solutions and beneficial effects of the present invention are described with reference to the above particular examples. Nevertheless, it will be understood that the above examples are not provided to limit the present invention. The invention is intended to cover various modifications and equivalent arrangements included within the spirit and scope of the claims.

1. A novel white light LED packaging structure comprising:
a blue-emitting chip;
a fluorescent wafer attached to the blue-emitting chip;
an anti-blue light reflection film(s) deposited on one surface of the fluorescent wafer, wherein the surface is attached to the blue-emitting chip.

2. The LED packaging structure according to claim 1, wherein the main component of the fluorescent wafer is Ce:YAG.

3. The LED packaging structure according to claim 2, wherein the main component of the anti-blue light reflection film(s) is one of titanium oxide, silicon oxide, aluminium oxide, and zirconium oxide, or any combination thereof.

4. The LED packaging structure according to claim 3, wherein the light transmission wave band of the anti-blue light reflection film(s) is 420 nm˜470 nm.

5. The LED packaging structure according to claim 4, wherein multiple layers of anti-blue light reflection films are used.

6. A process for manufacturing a novel white light LED packaging structure comprising the steps of:
(1) producing a Ce:YAG wafer by Czochralski process, temperature gradient process or Kyropoulos process;
(2) cutting and polishing the Ce:YAG wafer produced in step (1) to obtain a fluorescent wafer having desired size;
(3) depositing an anti-blue light reflection film(s) on one surface of the Ce:YAG wafer obtained in step (2) by physical vapor deposition; and
(4) attaching a blue-emitting chip on the deposited surface of the Ce:YAG wafer obtained in step (3) to carry out the packaging.
